(19) United States
(12) Patent Application Publication
(10) Pub. No.: US 2004/0244694 A1
(43) Pub. Date: Dec. 9, 2004

(54) Processing unit and processing method

(76) Inventor: Daisuke Hayashi, Nirasaki-Shi (JP)

Correspondence Address: SMITH, GAMBRELL & RUSSELL, LLP, 1850 M STREET, N.W., SUITE 800, WASHINGTON, DC, 20036, US

(21) Appl. No.: 10/250,771

(22) PCT Filed: Dec. 28, 2001
(86) PCT No.: PCT/JP01/11651

(30) Foreign Application Priority Data
Jan. 10, 2001 (JP) 2001-3098

(51) Int. Cl. C23C 16/00

(52) U.S. Cl. 118/728

(57) ABSTRACT

A processing unit of the invention is a processing unit of an object to be processed, which includes: a stage on which an object to be processed is placed; a processing container that contains the stage; and a stage-tilting mechanism that can tilt the stage with respect to a horizontal direction and that can change a direction of the tilt without rotating the stage as time passes.

### BACKGROUND OF THE INVENTION

1. Field of the Invention

The present invention relates to a processing unit and a processing method for carrying out a predetermined process to an object to be processed such as a semiconductor wafer and the like.

2. Description of the Related Art

Generally, in a semiconductor integrated circuit manufacturing process, a semiconductor wafer, which is an object to be processed, is subject to various processes including a film-forming process, an etching process, an oxidation diffusion process, an annealing process, a modification process and so on. In an etching process, for example, a metal or a metal compound such as Aluminum (Al), Copper (Cu), tungsten (W), tungsten silicide (WSi), titanium (Ti), titanium nitride (TiN), titanium silicide (TiSi), or the like, is deposited, or an insulating film such as a SiO₂ film, is deposited, or an insulating film such as SiO₂, is deposited to form a wiring pattern on a surface of a wafer or to fill up recesses between wiring lines and the like.

Subsequently, the deposited film formed as described above is etched and formed to be a desired pattern. In a general etching process, first of all, a resist film of an organic compound and the like is uniformly applied on a surface of the deposited film which is subject to etching. Then, the resist film is exposed and developed via a mask having a desired pattern. Accordingly, the aforementioned resist film is patterned. Thereafter, the resist film is placed on a hotplate and the like, and baked to become solid with a certain degree of heat. Using the patterned resist film as a mask, the deposited film of lower layer is etched, whereby it is possible to carry out a gap-forming process, a hole-forming process, and the like.

Incidentally, it is preferable to make the resist film thin in order to improve micro fabrication feature in the above-described patterning process. In addition, it is necessary for the resist film to be enhanced with resistance against etching as an etching mask. Therefore, in some cases, the resist film is divided into two layers of an upper layer and a lower layer, and a thin SiO₂ film of SOG (Spin On Glass) is provided between the upper and lower layers.

### DISCLOSURE OF THE INVENTION

As described above, a resist film is fixed on a surface of a deposited film of a wafer, and thereafter the resist film is baked to become solid in order to enhance a resistance thereof in the following etching step and the like. When these processes are not carried out uniformly and sufficiently, in the following etching step and the like, a crack may generate on the surface of the resist film or surface roughness of the resist film may become greater to a certain degree. Furthermore, there is also a problem that it needs a high temperature and a long time to bake to make solid only by heat.

A design rule in a conventional semiconductor manufacturing process is not so severe. Therefore, the aforementioned generation of the crack and increase in the surface roughness have not been so serious problems. However, when a line width is refined in the order of sub micron at a recent further request of enhanced integration and enhanced micro fabrication, the aforementioned generation of the crack and increase in the surface roughness may affect an etched form of a material to be etched.

Moreover, when various processes are carried out onto a semiconductor wafer, it is necessary for each process to be carried out uniformly to within a surface of the wafer. To achieve this, conventionally, a stage mechanism that holds the wafer is inventively designed, so that the stage mechanism rotates on its axis while keeping the wafer tilted, or the stage mechanism rotates on its axis and revolves around another axis at the same time (for example, Japanese Patent Laid-Open Publication (Kokai) No. 62-73726 and Japanese Patent Laid-Open Publication (Kokai) No. 5-326454, and so on).

However, the stage mechanism by which rotation on its axis and revolution are applied to the wafer itself at the same time may be very complicated, and may have a great difficulty in sufficiently keeping sealability. In addition, in a case wherein the wafer is rotated on its axis, in-plane uniformity may not be sufficient in the wafer process because a rotation center of the wafer cannot move.

Considering the above problems, this invention has been made to solve the problems effectively. An object of the present invention is to provide a processing unit and a processing method being capable of improving in-plane uniformity of an object to be processed in a process by changing a tilt direction of a stage in turn by means of a relatively simple composition.

The present invention is a processing unit for an object to be processed comprising: a stage on which an object to be processed is placed; a processing container that contains the stage; and a stage-tilting mechanism that can tilt the stage with respect to a horizontal direction and that can change a direction of the tilt as time passes, without rotating the stage.

According to the present invention, it is possible for the structure of the processing unit not to be so complicated, and it is also possible for the stage to swing in such a manner that the object to be processed placed on the stage is tilted with respect to the horizontal direction and that the direction of the tilt is changed as time passes without rotating the stage itself. Therefore, when a radiator of an energy-beam is provided at a ceiling part of the processing container, for example, the energy-beam can be radiated uniformly onto a surface of the object to be processed, whereby it is possible to improve in-plane uniformity of the object to be processed in the process.

Preferably, the stage-tilting mechanism has: a plurality of, for example three, stage-lifting rods connected to a reverse surface of the stage, each of which can be independently moved upward and downward; a driving part that can move upward and downward each of the plurality of stage-lifting rods; and a controlling part that controls the driving part.

For example, the controlling part is adapted to supply to the driving part respective driving signals that control respective height positions of the plurality of stage-lifting rods according to respective sine curves with phases different from each other by a predetermined angle.

In this case, preferably, a bias signal, whose level can be changed, is adapted to be commonly overlapped with the driving signals.

Accordingly, it is possible to cause the whole stage to shift up and down (move upward and downward) while swinging the stage itself. Therefore, it is possible to further improve in-plane uniformity of the object to be processed in the process.

In addition, an extendable bellows is preferably provided between a bottom part of the processing container and the stage, in order to maintain airtightness in the processing container and to allow the direction of the tilt of the stage to be changed.

In addition, for example, a plurality of electronic-beam tubes are provided at a ceiling part of the processing container, for radiating and diffusing an electronic-beam toward the stage.

Accordingly, it is possible to improve in-plane uniformity of the process by radiating the electronic-beam uniformly onto the surface of the object to be processed placed on the stage. In addition, it is possible for the process as described above to be performed at a lower temperature and in a shorter time compared with a process using only heat.

Furthermore, this invention is a processing method for an object to be processed comprising: a step of placing an object to be processed on a stage set in a processing container; and a step of tilting the stage with respect to a horizontal direction to change a direction of the tilt as time passes, without rotating the stage.

Preferably, the processing method further comprises a step of radiating and diffusing an electronic-beam from a plurality of electronic-beam tubes onto a surface of the object to be processed.

### BRIEF DESCRIPTION OF THE DRAWINGS

FIG. 1 is a schematic cross-sectional view showing a processing unit according to the present invention;

FIG. 2 is a view showing an arrangement of electronic-beam tubes provided at a ceiling part of the processing container;

FIG. 3 is a view showing one example of radiation patterns of an object to be processed which is radiated by electronic-beams radiated from the electronic-beam tubes;

FIG. 4 is a perspective view showing an arrangement of stage-lifting rods of a stage-lifting mechanism;

FIG. 5 is a schematic diagram for explaining a swinging condition of a stage;

FIG. 6 is a signal wave chart explaining driving signals supplied to driving systems of the stage-lifting rods;

FIG. 7 is a side view showing an operation of the stage;

FIG. 8 is a view showing one example of change in actual radiation patterns by electric-beams; and

FIG. 9 is a schematic cross-sectional view showing a modification of the processing unit according to the present invention.

### DESCRIPTION OF THE PREFERRED EMBODIMENTS

Hereinafter, an embodiment of a processing unit and a processing method according to the present invention will be described in detail based on the accompanying drawings.

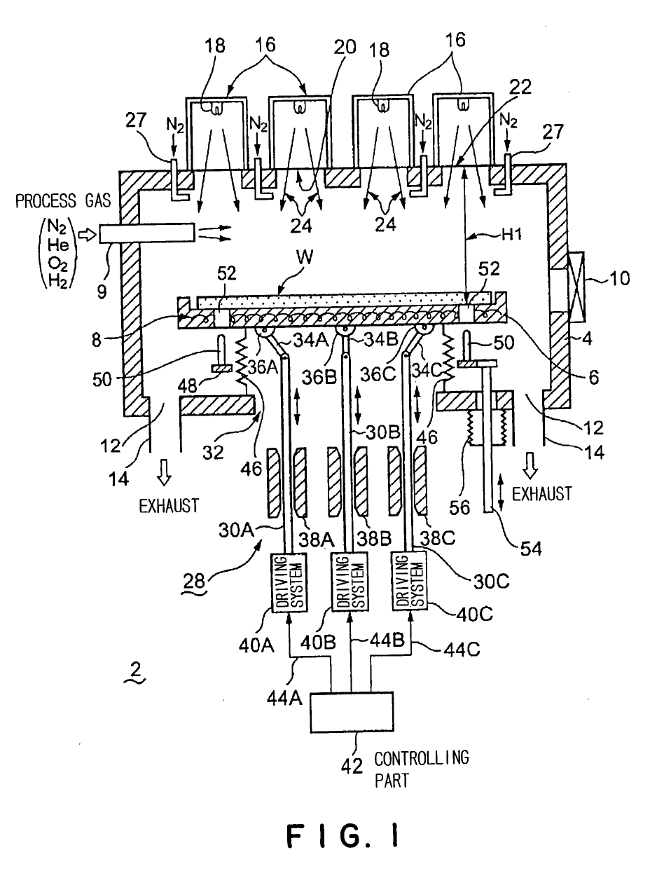

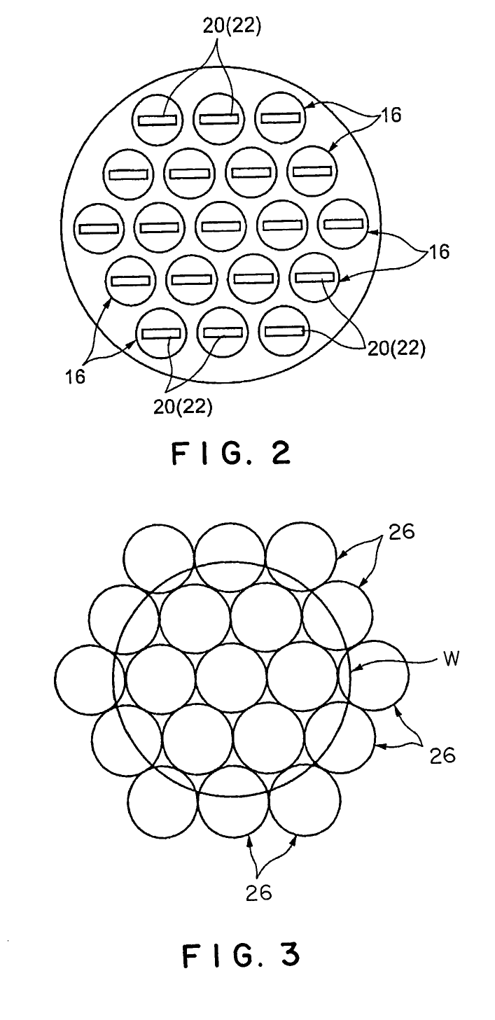

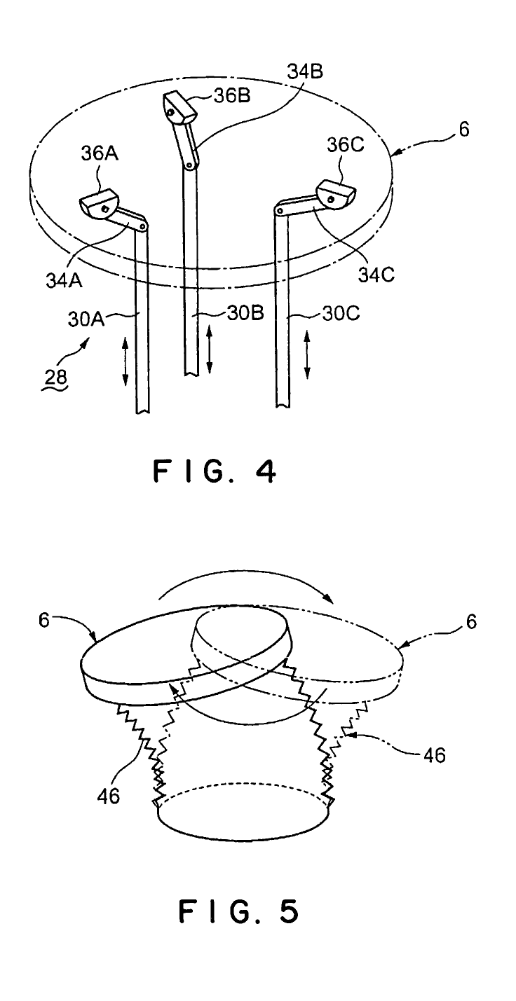

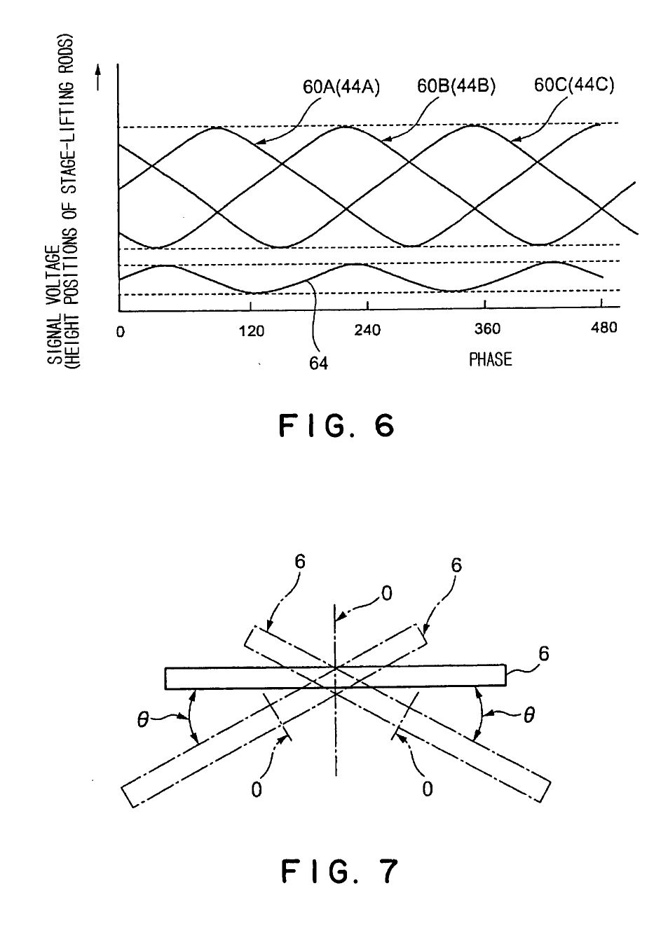

FIG. 1 is a schematic cross-sectional view showing a processing unit according to the present invention. FIG. 2 is a view showing an arrangement of electronic-beam tubes provided at a ceiling part of a processing container. FIG. 3 is a view showing one example of radiation patterns of an object to be processed which is radiated by electronic-beams radiated from the electronic-beam tubes. FIG. 4 is a perspective view showing an arrangement of stage-lifting rods of a stage-lifting mechanism. FIG. 5 is a schematic diagram for explaining a swinging condition of a stage. FIG. 6 is a signal wave chart explaining driving signals supplied to driving systems of the stage-lifting rods. FIG. 7 is a side view showing an operation of the stage.

As shown in FIG. 1, a processing unit 2 includes a processing container 4 which is formed to be cylindrical or box shape and inside of which is allowed to be evacuated.

The processing container 4 is made of, for example, aluminum or the like. A stage 6, on whose upper surface a semiconductor wafer W, for example, as an object to be processed is placed, is arranged in the processing container 4. This stage 6 is formed to be in a disk shape and made of, for example, a carbon material, an aluminum compound such as AlN, or the like. A resistance-heating element 8 is embedded in the stage 6 as a heater for heating the semiconductor wafer W placed on the stage 6.

A process gas nozzle 9 is provided at a side wall of the processing container 4 as a gas supplier for supplying a necessary process gas into the processing container 4. In addition, a gate valve 10 being opened and closed in transferring the wafer W in and out of the processing container 4 is also provided at the side wall of the processing container 4.

Moreover, an exhausting opening 12 is provided at a bottom peripheral part of the processing container 4. An exhausting pipe 14 having a not-shown vacuum pump is connected to the exhausting opening 12. Thereby, inside of the processing container 4 can be evacuated.

A plurality of electronic-beam tubes 16 are provided at a ceiling part of the processing container 4 as energy sources of radiation beams which perform a process onto the semiconductor wafer W. The electronic-beam tubes 16 are arranged substantially evenly over a substantial whole region of the ceiling part of the container as shown in FIGS. 1 and 2 in order to radiate a substantial whole region of the wafer surface. Transmitting windows 20 formed to be rectangular shape are provided at lower ends of the respective electronic-beam tubes 16. The transmitting windows 20 have thin silicon films 22 which can pass an electronic-beam therethrough. Filaments 18 are provided in the respective electronic-beam tubes 16. An electron generated by the filament 18 is accelerated in a beam condition by a not-shown accelerating electrode and is introduced into the processing container 4 through the above transmitting window 20. The introduced electronic-beam 24 is adapted to be diffused and radiated onto the surface of the wafer. FIG. 2 shows a state wherein the nineteen electronic-beam tubes 16 are arranged. FIG. 3 shows radiation patterns 26 which the electronic-beams 24 radiated by the respective electronic-beam tubes 16 form on the surface of the wafer W. Here, the arrangement of the respective electronic-beam tubes 16 and a distance H1 between each of the electronic-beam tubes 16 and the stage 6 are set in such a manner that the substantially round-shaped radiation patterns 26 are substantially circumscribed with respect to each other when the stage 6 and the wafer W are in a horizontal condition at a reference horizontal position.

Coolant gas nozzles 27 are provided at the ceiling part of the container in such a manner that they are opened in a vicinity of the transmitting windows 20 of the respective electronic-beam tubes 16. An inert nitrogen gas, for example, as a coolant gas is spouted from the coolant gas nozzle 27.

Thereby, the transmitting windows 20, which tend to be heated by the electronic-beams 24, are adapted to be cooled down.

The stage 6 is supported so as to swing in a tilted condition by a stage-tilting mechanism 28, which has a feature of the present invention (refer to FIG. 5). Specifically, as shown in FIG. 4, the stage-tilting mechanism 28 includes more than or equal to three, in the illustrated example three, stage-lifting rods 30A, 30B, 30C, which are arranged at substantially equal intervals and in substantially isotropic directions from a center of the aforementioned circular stage 6. Each of rods 30A to 30C extends downward through a rod-hole 32 having a large bore diameter provided at the bottom part of the container. Short-length auxiliary arms 34A, 34B, 34C are pivotably connected to upper ends of the respective stage-lifting rods 30A to 30C, for example, by pin connections respectively. Tips of the respective auxiliary arms 34A, 34B, 34C are pivotably connected, for example, by pin connections to connecting protrusions 36A, 36B, 36C provided on a reverse surface of the stage 6 at approximately 120 degree-intervals and in isotropic directions by serving the center of the stage as a center thereof. Therefore, by moving upward and downward the respective stage-lifting rods 30A to 30C while maintaining predetermined differences of phase angles with respect to each other, the stage 6 is changed in a tilt direction thereof so as to swing temporally (as time passes) with a condition that the stage is tilted by a predetermined angle, without rotating the stage 6 itself as also shown in FIG. 5. In other words, it is possible to make the stage 6 perform a precessing movement.

There are guiding sleeves 38A to 38C respectively provided along paths of the respective stage-lifting rods 30A to 30C. The guiding sleeves 38A to 38C are capable of guiding the respective stage-lifting rods 30A to 30C so that the stage-lifting rods 30A to 30C can be moved upward and downward smoothly. Additionally, driving systems 40A to 40C composed of linear motors and so on, each of which generates a driving force to move the rod upward and downward, are connected at lower ends of the respective stage-lifting rods 30A to 30C. By controlling the driving systems 40A to 40C, upward and downward movements of the respective rods 30A to 30C are controlled. Operations of the respective driving systems 40A to 40C are adapted to be controlled by driving signals 44A, 44B, 44C from a controlling part 42 composed of, for example, a microcomputer and the like.

An extendable bellows 46 having a large bore diameter made of a ricrac-shaped metal plate is provided and connected between a periphery part on the reverse surface of the stage 6 and the bottom part of the container on which the rod-hole 32 is formed, in such a manner that all the stage-lifting rods 30A to 30C are surrounded thereby. This enables airtightness in the processing container 4 to be maintained and allows the aforementioned stage 6 to be moved upward and downward.

An annular joint ring 48 is arranged at an outer circumferential side of the bellows 46 and below the stage 6. A plurality of, for example three, lifting pins 50 (only two of them are shown in FIG. 1) stand from the joint ring 48 at substantially constant intervals. The joint ring 48 is connected to a pushing-up bar 54 which is moved upward and downward through the bottom part of the container. An extendable bellows 56 is provided between a lower part of the pushing-up bar 54 and a lower surface of the bottom part of the container in order to allow the pushing-up bar 54 to be moved upward and downward while keeping airtightness in the processing container 4. By the upward and downward movement of the pushing-up bar 54 and the joint ring 48, the lifting pins 50 are adapted to be capable of passing through lifting pin holes 52 provided at the stage 6, abutting a lower surface of the wafer W and bringing up or down the wafer W.

Next, as one example of a processing method according to the present invention, which is carried out using the processing unit as composed above, a modification process of a resist film, for example, is explained.

First of all, the gate valve 10 provided at the side wall of the processing container 4 is opened, and a wafer W is transferred into the processing container 4 by a transfer arm (not shown) . On the other hand, the lifting pins 50 are pushed up and protrude from the stage 6. The wafer W is taken over onto the protruding lifting pins 50. Then, the lifting pins 50 go downward by bringing down the pushing-up bar 54, whereby the wafer W is placed on the stage 6. Note that a resist film is to be uniformly coated on the surface of this wafer W in a previous process.

Next, a mixture gas as a process gas, for example a mixture gas of N₂, He, O₂, or H₂, in this embodiment N₂ gas (O₂ concentration of less than 300 ppm), is introduced into the processing container 4 through the process gas nozzle 9 from a not-shown process gas source. Internal atmosphere is sacked and evacuated from the exhausting opening 12 so that the processing container 4 is set to be a predetermined degree of vacuum. Furthermore, the wafer W is heated and kept to be at a predetermined temperature, for example in a range from room temperature to 500° C., in this embodiment approximately 100° C., by the resistance-heating element 8 in the stage 6.

Subsequently, a plurality of the electronic-beam tubes 16 provided at the ceiling part of the processing container 4 are driven and thus the electronic-beams 24 are set to be at an accelerating energy within a range from 5 to 15 keV, in this embodiment 6 keV, so as to be diffused and radiated from the respective electronic-beam tubes 16. Thereby, the surface of the wafer W on the stage 6 is radiated by the electronic-beams 24 (dose amount of 2 mC), and thus processes from a sintering proces to a modification process are carried out to the resist film formed on the surface of the wafer W.

Concurrently with this, the stage-tilting mechanism 28 supporting the stage 6 is driven, so that the stage 6 is tilted with respect to a horizontal direction and that the tilt direction thereof is changed as time passes without rotating the stage 6. That is, a so-called precessing action as shown in FIG. 5 is performed. In order to perform the precessing action, the respective three stage-lifting rods 30A to 30C may be moved upward and downward successively in turn while shifting by predetermined intervals with respect to each other.

Specifically, as shown in FIG. 6, driving singals 44A, 44B, 44C (refer to FIG. 1) including components of three sine curve signals 60A, 60B, 60C, whose phases are shifted by 120 degrees in electrical degree with respect to each other, are supplied to the respective driving systems 40A, 40B, 40C.

The respective stage-lifting rods 30A, 30B, 30C are moved upward and downward according to the respective sine components. Thereby, as shown in FIG. 7, the stage 6 performs the so-called precessing movement in a condition keeping a substantially constant angle θ with respect to the horizontal direction, without rotated. This angle θ is different depending on a stroke amount in the upward and downward direction of the respective stage-lifting rods 30A to 30C, but it is preferred to be set the angle within a range of, for example, from 5 to 20 degrees or so.

In this case, as shown in FIG. 7, a position of a center O of the stage 6 is moved a little in a radial direction thereof due to tilt of the stage 6. That is, the stage 6 is to perform an eccentric movement. However, as each of the auxiliary arms 34A to 34C pivotably connected to the upper ends of the stage-lifting rods 30A to 30C bends with respect to each of the stage-lifting rods 30A to 30C, the eccentric amount at that time may be absorbed.

As described above, due to the so-called precessing movement of the stage 6, a distance from the electronic-beam tubes 16 of each portion on the stage 6 becomes larger and smaller. Therefore, in each of the respective round-shaped radiation patterns 26 formed by the electronic-beams shown in FIG. 3, a diameter thereof becomes larger and smaller in turn. Thereby, the electronic-beams may be radiated onto the surface of the wafer W substantially uniformly without biased. That is, in-plane uniformity in the wafer process may be considerably improved.

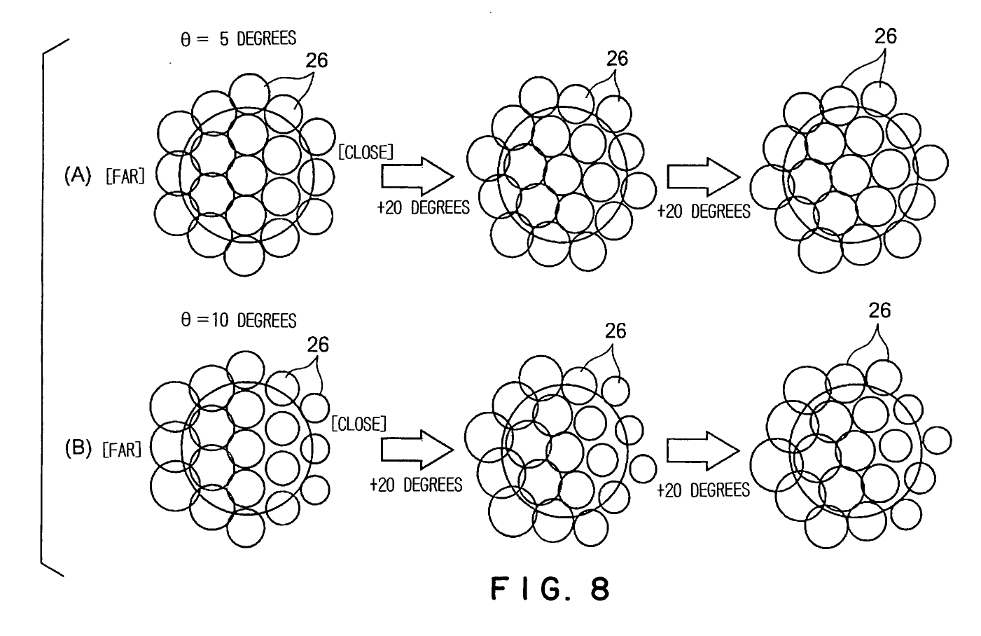

Here, an example of actual changes in radiation patterns by the electronic-beams will be described with reference to FIG. 8. FIG. 8 shows a calculation result by a simulation wherein a tilted wafer rotates with respect to a central axis of the wafer. This enables a preferred tilt angle in a composition of the present application to be approximately obtained. In FIG. 8, FIG. 8(A) illustrates a case wherein the tilt angle θ of the stage 6 (wafer) is 5 degrees, FIG. 8(B) illustrates a case wherein the tilt angle θ is 10 degrees, and both illustrate conditions that precessing is respectively proceeded by 20 degrees from left to right while fixing the wafer positions constant. In addition, the distance H1 between the stage 6 and the electronic-beam tubes 16 (refer to FIG. 1) is set to be 60 mm.

As shown in FIG. 8, the radiation patterns 26 which are positioned more distantly from the electronic-beam tubes 16 (left-hand in FIG. 8) have larger diameters so as to generate overlapping portions due to overlapping of the adjacent radiation patterns. The overlapping portions become broader as the tilt angle θ becomes lager. Incidentally, when the tilt angle θ becomes too large, for example more than 20 degrees, the radiation patterns (right-hand in FIG. 8) 26 which are positioned more closely to the electronic-beam tubes 16 are not radiated onto the wafer, which is not preferred. On the other hand, when this tilt angle θ is smaller than 5 degrees, radiation amounts in boundary portions between the adjacent radiation patterns tend to be insufficient compared with other portions, so that it is not possible to keep the in-plane uniformity in the wafer process, which is not preferred.

Although it takes several minutes or so for the modification process, it is preferable to perform the precessing movement at least once or more, for example a plurality of times or so, during the process in order to improve the in-plane uniformity in the wafer process. In this case, it is desirable to control frequency at most not more than once per second from viewpoints of dispersion of dust, load to the stage-tilting mechanism 28, and the like.

Additionally, when the stage 6 performs the precessing movement as described above, a shift amount of the center portion of the stage in an upward and downward direction is less in comparison with other portions. Therefore, in order to compensate this, it is preferable to add an upward and downward movement to the whole stage 6 in addition to the precessing movement. For this purpose, as shown in FIG. 6, it is preferable to commonly add and overlap an level-variable bias signal, for example a sine-curve bias signal 64, to the respective driving signals 44A to 44C. Accordingly, the diameters of the radiation patterns at the center part of the wafer vary sufficiently greatly. Therefore, it is possible to improve the in-plane uniformity of the wafer process further considerably. Incidentally, a period of the bias signal 64 is preferably different from periods of the aforementioned driving signals 44A to 44C. In this case, it is possible to prevent a particular position on the wafer from intensively accessing most closely to the electronic-beam tubes 16.

According to the above described embodiment, it was possible to control the in-plane uniformity of the wafer by radiation of the electronic-beams to be less than ±10%.

Incidentally, the distance H1 between the aforementioned stage 6 and the electronic-beam tubes 16 are not limited to 60 mm. The distance H1 is practically preferred to be within a range from 20 to 90 mm or so, although it depends on a diffusion angle of the electronic-beams 24. Moreover, a pressure in the processing container 4 when radiating the electronic-beam, i.e. a process pressure, may be atmosphere pressure. However, considering the linearity (forthrightness) or effectiveness of an electron, it is desirable that the process pressure is not more than 66.7 kPa (500 Torr), more preferably not more than 40 kPa (300 Torr).

As the process pressure becomes lower, the linearity of an electron increases so that a chemical adverse affect by an impurity gas is decreased. However, there is no significant difference when it is not more than 1330 Pa (10 Torr) . Therefore, a lower limit of the processing pressure is preferably 1330 Pa (10 Torr) or so.

Furthermore, when the electronic-beam is not radiated onto a resist film (ArF resist) , a surface roughness of the resist film after the etching process (etching gas: CF₄/O₂/Ar) was approximately 3.04 nm. On the other hand, when the electronic-beam is radiated onto a resist film uniformly as described above to carry out a modification process, a surface roughness of the resist film after the etching process was approximately 0.27 nm. Accordingly, it was recognized that resistance of the resist film against etching is enhanced uniformly and that the feature thereof is improved significantly. As a result, it was recognized that when patterning the resist film, the patterning process can be also carried out with excellent straightness without creating a refine irregularity on a boundary of gap portions thereof.

For example, when a patterning process of an inter-layer insulation film is carried out, in which a resist film is configured to be multi-layer and a Sio₂ film such as SOG is adapted to lie between the resist layers, the modification process by the electronic-beam as described above may be performed every time the resist layer is applied. This enables to prevent a crack form generating in the resist film.

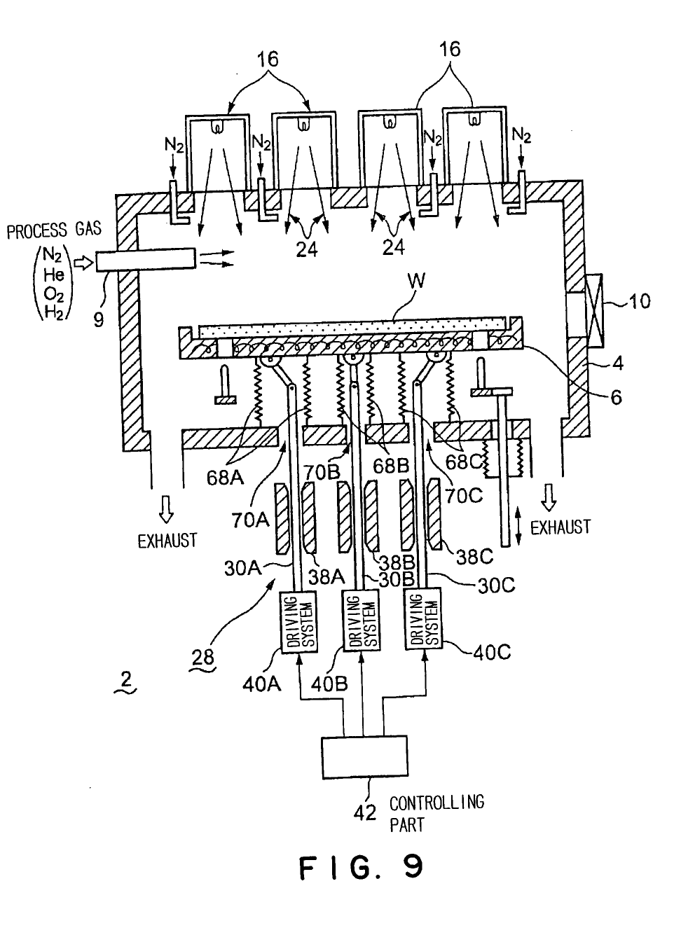

Furthermore, in the aforementioned embodiment, the bellows 46 having a large bore diameter is provided in such a manner that it surrounds the whole outer circumferential of the three stage-lifting rods 30A to 30C, but it should not be limited thereto. For example, as shown in FIG. 9, bellows 68A, 68B, 68C having small bore diameters may be provided in such a manner that they respectively surround each of the stage-lifting rods 30A to 30C separately. In this case, as for the rod holes provided at the bottom part of the container, rod holes 70A, 70B, 70C having small bore diameters may be provided respectively corresponding to the rods 30A to 30C.

Note that although a case of a modification process of a resist film by using an electronic-beam is explained as an example in the above embodiment, it should not be limited thereto. For example, this invention is applicable to control of permittivity of an organic-silicon oxide film, and the like.

Furthermore, the composition to make the stage 6 perform the processing movement as described above is not limited to a processing unit for modification process using an electronic-beam, but is also applicable to a film-forming unit, an etching process unit using plasma, an oxidation diffusion process unit, an annealing process unit, and the like.

Still furthermore, an object to be processed is not limited to a semiconductor wafer, but be a glass substrate, an LCD substrate, and the like.

1. A processing unit for an object to be processed comprising:
a stage on which an object to be processed is placed;
a processing container that contains the stage; and
a stage-tilting mechanism that can tilt the stage with respect to a horizontal direction and that can change a direction of the tilt as time passes, without rotating the stage.

2. A processing unit according to claim 1, wherein
the stage-tilting mechanism has:
a plurality of stage-lifting rods connected to a reverse surface of the stage, each of which can be independently moved upward and downward;
a driving part that can move upward and downward each of the plurality of stage-lifting rods; and
a controlling part that controls the driving part.

3. A processing unit according to claim 2, wherein
the controlling part is adapted to supply to the driving part respective driving signals that control respective height positions of the plurality of stage-lifting rods according to respective sine curves with phases different from each other by a predetermined angle.

4. A processing unit according to claim 3, wherein
a bias signal, whose level can be changed, is adapted to be commonly overlapped with the driving signals.

5. A processing unit according to any of claims 1 to 4, wherein
an extendable bellows is provided between a bottom part of the processing container and the stage, in order to maintain airtightness in the processing container and allow the direction of the tilt of the stage to be changed.

6. A processing unit according to any of claims 1 to 4, wherein
a plurality of electronic-beam tubes is provided at a ceiling part of the processing container, for radiating and diffusing an electronic beam toward the stage.

7. A processing method for an object to be processed comprising:
a step of placing an object to be processed on a stage set in a processing container; and
a step of tilting the stage with respect to a horizontal direction to change a direction of the tilt as time passes, without rotating the stage.

8. A processing method according to claim 7, further comprising:
a step of radiating and diffusing an electronic beam from a plurality of electronic-beam tubes onto a surface of the object to be processed.
